(19) United States
(12) Patent Application Publication
(10) Pub. No.: US 2010/0320526 A1
(43) Pub. Date: Dec. 23, 2010

(54) NONVOLATILE SEMICONDUCTOR MEMORY DEVICE AND METHOD FOR MANUFACTURING SAME

(75) Inventors: Masaru KIDOH, Tokyo (JP); Ryota KATSUMATA, Kanagawa-ken (JP); Masaru KITO, Kanagawa-ken (JP); Yoshiaki FUKUZUMI, Kanagawa-ken (JP); Hiroyasu TANAKA, Tokyo (JP); Yosuke KOMORI, Kanagawa-ken (JP); Megumi ISHIDUKI, Kanagawa-ken (JP); Tomoko FUJIWARA, Kanagawa-ken (JP); Yoshimasa MIKAJIRI, Kanagawa-ken (JP); Shigeto OOTA, Kanagawa-ken (JP); Hideaki AOCHI, Kanagawa-ken (JP); Ryouhei KIRISAWA, Kanagawa-ken (JP); Junya MATSUNAMI, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/727,730

(22) Filed: Mar. 19, 2010

(30) Foreign Application Priority Data
Jun. 22, 2009 (JP) 2009-147605

(51) Int. Cl. H01L 29/792; H01L 21/336

(52) U.S. Cl. 257/324; 438/261; 257/E29.309; 257/E21.409

(57) ABSTRACT

A nonvolatile semiconductor memory device includes: a semiconductor substrate; a memory unit; and a circuit unit provided between the semiconductor substrate and the memory unit. The memory unit includes: a stacked structural unit having electrode films alternately stacked with inter-electrode-film insulating films; a semiconductor pillar piercing the stacked structural unit; and a storage unit provided corresponding to an intersection between the electrode films and the semiconductor pillar. The circuit unit includes first and second transistors having different conductivity type, a first interconnect, and first and second contact plugs. The first interconnect includes silicide provided on a side of the first and second transistors opposite to the semiconductor substrate. The first contact plug made of polysilicon of the first conductivity type connects the first interconnect to the first transistor. The second contact plug made of polysilicon of the second conductivity type connects the first interconnect to the second transistor.

### CROSS-REFERENCE TO RELATED APPLICATIONS

This application is based upon and claims the benefit of priority from the prior Japanese Patent Application No. 2009-147605, filed on Jun. 22, 2009; the entire contents of which are incorporated herein by reference.

### BACKGROUND

1. Field

Embodiments of the invention relate generally to a nonvolatile semiconductor memory device for which electrical overwriting of data is possible and a method for manufacturing the same.

2. Background Art

Even higher capacities are desirable for nonvolatile semiconductor memory devices and particularly flash memory utilized in various applications. The downscaling thereof has progressed acceleratingly, and limitations of downscaling are being approached. While downscaling must be relied upon to increase the capacities of conventional structures having memory cells, circuit elements, and the like disposed in a plane, such downscaling has reached limitations.

To solve such problems, flash memory has been proposed having a three dimensional structure in which memory cells (memory strings), selection gates, and the like conventionally disposed in a plane are disposed in a direction perpendicular to the substrate (for example, refer to JP-A 2007-266143 (Kokai)).

In flash memory having a three dimensional structure, the conventional structure is rotated 90 degrees to the direction perpendicular to the substrate. In such technology, a stacked unit including electrode films forming word lines alternately stacked with insulating films is formed on a silicon substrate; and through-holes are collectively made in the stacked unit. Then, for example, a charge storage layer is formed on the side faces of the through-holes; and silicon pillars are formed by filling polysilicon into the interiors of the through-holes. Thereby, memory cells are formed at the intersections among the silicon pillars and each of the electrode films. Selection gate electrodes are provided in the upper portion of the stacked unit and silicon pillars pierce the selection gate electrodes to form selection gate transistors. In addition to downscaling, a flash memory having a three dimensional structure can increase capacity by stacking the memory cells in the perpendicular direction.

To further reduce the chip surface area of such a flash memory having a three dimensional structure, it may be considered to form a peripheral circuit on the substrate and subsequently form the memory cells thereupon. When forming the memory cells, high-temperature processing may be performed at, for example, 1000° C. or more; and it is necessary for the peripheral circuit to withstand such temperatures. In particular, the contact between transistors and interconnect layers included in the peripheral circuit easily deteriorate at high temperatures. Therefore, it is necessary to develop interconnect layers and contacts having characteristics that do not deteriorate even when formed in a portion below the memory cells.

### SUMMARY

According to an aspect of the invention, there is provided a nonvolatile semiconductor memory device, including: a semiconductor substrate; a memory unit; and a circuit unit provided between the semiconductor substrate and the memory unit, the memory unit including: a stacked structural unit having a plurality of electrode films alternately stacked with a plurality of inter-electrode-film insulating films in a first direction perpendicular to a major surface of the substrate; a first semiconductor pillar piercing the stacked structural unit in the first direction; and a first storage unit provided corresponding to an intersection between the electrode films and the first semiconductor pillar, the circuit unit including: a first transistor having a first source region of a first conductivity type and a first drain region of the first conductivity type; a second transistor having a second source region of a second conductivity type and a second drain region of the second conductivity type; a first interconnect including silicide provided on a side of the first transistor and the second transistor opposite to the semiconductor substrate; a first contact plug made of polysilicon of the first conductivity type electrically connecting the first interconnect to at least one selected from the first source region and the first drain region; and a second contact plug made of polysilicon of the second conductivity type electrically connecting the first interconnect to at least one selected from the second source region and the second drain region.

According to another aspect of the invention, there is provided a method for manufacturing a nonvolatile semiconductor memory device, including: forming a first transistor and a second transistor on a major surface of a semiconductor substrate, the first transistor including a first source region of a first conductivity type and a first drain region of the first conductivity type, the second transistor including a second source region of a second conductivity type and a second drain region of the second conductivity type; forming a first contact plug, a second contact plug, and a first interconnect layer, the first contact plug being made of polysilicon of the first conductivity type and aligned in a first direction perpendicular to the major surface to connect to at least one selected from the first source region and the first drain region, the second contact plug being made of polysilicon of the second conductivity type and aligned in the first direction to connect to at least one selected from the second source region and the second drain region, the first interconnect layer including silicide and being connected to one selected from the first contact plug and the second contact plug; and forming a memory unit above the first interconnect layer, the memory unit including: a stacked structural unit having a plurality of electrode films alternately stacked with a plurality of inter-electrode-film insulating films in the first direction; a first semiconductor pillar piercing the stacked structural unit in the first direction; and a first storage unit provided corresponding to an intersection between the electrode films and the first semiconductor pillar.

### BRIEF DESCRIPTION OF THE DRAWINGS

FIG. 1 is a schematic cross-sectional view illustrating the configuration of a nonvolatile semiconductor memory device according to a first embodiment of the invention;

FIG. 2 is a schematic perspective view illustrating the configuration of the nonvolatile semiconductor memory device according to the first embodiment of the invention;

FIG. 3 is a schematic cross-sectional view illustrating the configuration of a portion of the nonvolatile semiconductor memory device according to the first embodiment of the invention;

FIG. 4 is a schematic plan view illustrating the configuration of electrode films of the nonvolatile semiconductor memory device according to the first embodiment of the invention;

FIG. 5 is a schematic cross-sectional view illustrating the configuration of a circuit unit of the nonvolatile semiconductor memory device according to the first embodiment of the invention;

FIG. 6 is a schematic cross-sectional view illustrating the configuration of a circuit unit of another nonvolatile semiconductor memory device according to the first embodiment of the invention;

FIG. 7 is a schematic cross-sectional view illustrating the configuration of a circuit unit of another nonvolatile semiconductor memory device according to the first embodiment of the invention;

FIG. 8 is a schematic cross-sectional view illustrating the configuration of a portion of another nonvolatile semiconductor memory device according to the first embodiment of the invention;

FIG. 9 is a schematic cross-sectional view illustrating the configuration of another nonvolatile semiconductor memory device according to the first embodiment of the invention;

FIG. 10 is a schematic perspective view illustrating the configuration of another nonvolatile semiconductor memory device according to the first embodiment of the invention;

FIG. 11 is a flowchart illustrating a method for manufacturing a nonvolatile semiconductor memory device according to a second embodiment of the invention;

FIGS. 12A and 12B are schematic cross-sectional views in order of the processes, illustrating the method for manufacturing the nonvolatile semiconductor memory device according to the second embodiment of the invention; and

FIG. 13 is a schematic cross-sectional view in order of the processes, continuing from FIG. 12B.

### DETAILED DESCRIPTION

Exemplary embodiments of the invention will now be described with reference to the drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

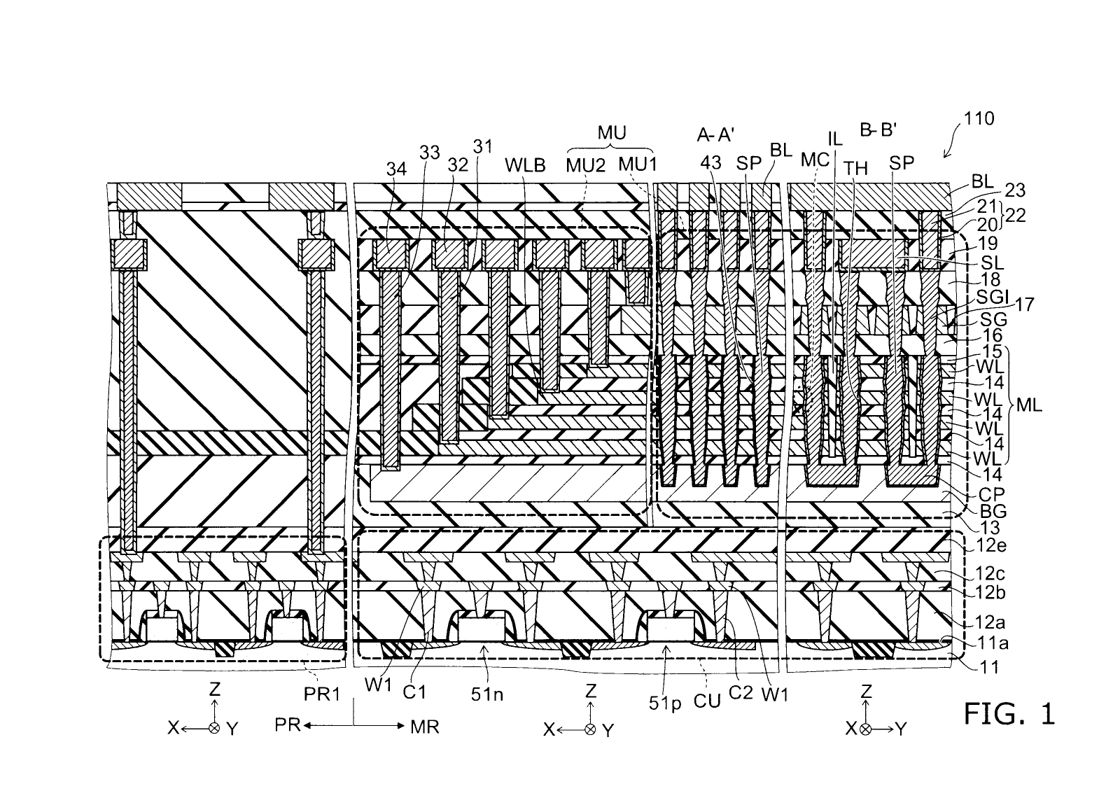

FIG. 1 is a schematic cross-sectional view illustrating the configuration of a nonvolatile semiconductor memory device according to a first embodiment of the invention.

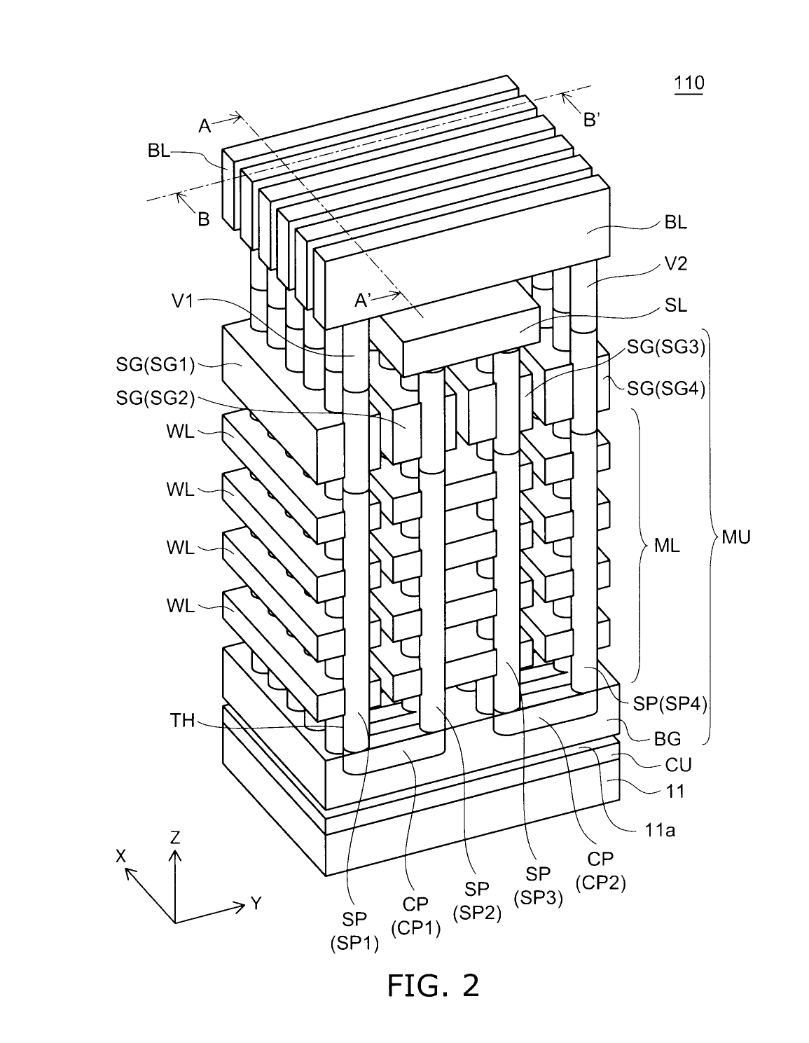

FIG. 2 is a schematic perspective view illustrating the configuration of the nonvolatile semiconductor memory device according to the first embodiment of the invention.

For easier viewing of the drawing in FIG. 2, only the conductive portions are illustrated, and the insulating portions are omitted.

A nonvolatile semiconductor memory device 110 according to the first embodiment of the invention is a three dimensional stacked flash memory.

As illustrated in FIG. 1, the nonvolatile semiconductor memory device 110 includes a semiconductor substrate 11 made of, for example, monocrystalline silicon.

A memory array region MR and a peripheral region PR are set in the semiconductor substrate 11 of this specific example. Memory cells are formed in the memory array region, and the peripheral region PR is provided, for example, peripherally to the memory array region MR. In the peripheral region PR, various peripheral region circuits PR1 are provided on the semiconductor substrate 11. However, the invention is not limited thereto. Only the memory array region MR may be provided on the semiconductor substrate 11, and the peripheral region PR may be omitted.

A circuit unit CU is provided on the semiconductor substrate 11 in the memory array region MR. A memory unit MU is provided on the circuit unit CU. In other words, the circuit unit CU is provided on the semiconductor substrate 11 in a portion below the memory unit MU. An inter-layer insulating film 13 made of, for example, silicon oxide is provided between the circuit unit CU and the memory unit MU.

The memory unit MU includes a matrix memory cell unit MU1 and an interconnect connection unit MU2. The matrix memory cell unit MU1 includes memory cell transistors arranged in a three dimensional matrix configuration. The interconnect connection unit MU2 connects interconnects of the matrix memory cell unit MU1.

FIG. 2 illustrates the configuration of the matrix memory cell unit MU1.

Namely, FIG. 1 illustrates a portion of the cross section along line A-A′ of FIG. 2 and a portion of the cross section along line B-B′ of FIG. 2 as the matrix memory cell unit MU1.

As illustrated in FIG. 1 and FIG. 2, a stacked structural unit ML is provided on a major surface 11a of the semiconductor substrate 11 in the matrix memory cell unit MU1. The stacked structural unit ML includes multiple electrode films WL alternately stacked with multiple first insulating films 14 (insulating films, inter-electrode-film insulating films) in a direction perpendicular to the major surface 11a.

An XYZ orthogonal coordinate system will now be introduced for convenience of description in the specification of the application. In this coordinate system, a direction perpendicular to the major surface 11a of the semiconductor substrate 11 is taken as a Z axis direction (the first direction). One direction in a plane parallel to the major surface 11a is taken as a Y axis direction (the second direction). A direction perpendicular to the Z axis and the Y axis is taken as the X axis direction (the third direction).

The stacking direction of the electrode films WL and the first insulating films 14 in the stacked structural unit ML is the Z axis direction. In other words, the electrode films WL and the first insulating films 14 are provided parallel to the major surface 11a.

A semiconductor pillar SP (a first semiconductor pillar SP1) is provided to pierce the stacked structural unit ML in the Z axis direction. The semiconductor pillar SP is formed by filling a semiconductor into a through-hole TH that pierces the stacked structural unit ML in the Z axis direction.

Memory cells MC are provided corresponding to the intersections between the semiconductor pillar SP and the electrode films WL of the stacked structural unit ML.

In this specific example, a charge storage layer 43 is provided between the electrode films WL and a side face of the semiconductor pillar SP via an insulating layer described below. The charge storage layer 43 forms the storage unit of the memory cells MC.

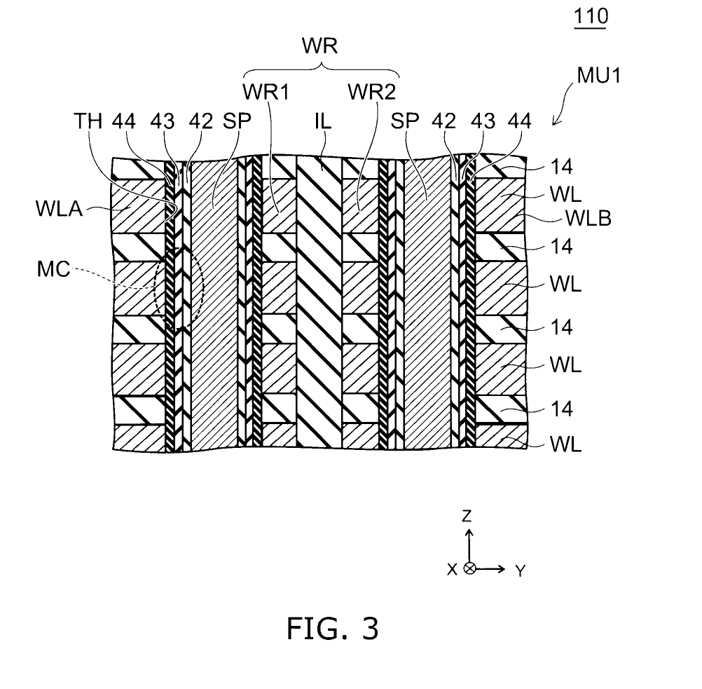

FIG. 3 is a schematic cross-sectional view illustrating the configuration of a portion of the nonvolatile semiconductor memory device according to the first embodiment of the invention.

Namely, FIG. 3 illustrates the configuration of the matrix memory cell unit MU1.

In the nonvolatile semiconductor memory device 110, a second insulating film 44 (the outer side insulating film), the charge storage layer 43, and a third insulating film 42 (the inner side insulating film) are provided on an inner side of the through-hole TH; and the semiconductor pillar SP is provided on the inner side thereof as illustrated in FIG. 3.

In other words, the nonvolatile semiconductor memory device 110 further includes a first outer side insulating film (the second insulating film 44) and a first inner side insulating film (the third insulating film 42), where the first outer side insulating film is provided between the storage unit (the charge storage layer 43) and each of the electrode films WL, and the first inner side insulating film is provided between the storage unit (i.e., the first storage unit, the charge storage layer 43) and the first semiconductor pillar SP.

The electrode film WL may include any conductive material. For example, amorphous silicon or polysilicon having an impurity introduced to provide electrical conductivity may be used; and metals, alloys, etc., also may be used. A prescribed electrical signal is applied to the electrode film WL; and the electrode film WL functions as a word line of the nonvolatile semiconductor memory device 110.

The first insulating film 14, the second insulating film 44, and the third insulating film 42 may include, for example, silicon oxide (silicon oxide).

The first insulating film 14 functions as an inter-layer insulating film to insulate the electrode films WL from each other.

The memory cells MC are formed corresponding to the portions where the electrode films WL intersect the semiconductor pillar SP. In the memory cell MC, the charge storage layer 43 forms the storage unit; the second insulating film 44 functions as a blocking insulating layer; and the third insulating film 42 functions as a tunneling insulating film.

The charge storage layer 43 may include, for example, a silicon nitride film and functions as a storage unit by storing or emitting charge due to an electric field applied between the semiconductor pillar SP and the electrode films WL. The charge storage layer 43 may be a single-layer film or a stacked film.

Also, the second insulating film 44 and a third insulating film 42 may be single-layer films or stacked films.

Thus, in the nonvolatile semiconductor memory device 110, cell transistors including the charge storage layer 43 are formed at the portions where the electrode films WL intersect the semiconductor pillar SP. The cell transistors are arranged in a three dimensional matrix configuration. The charge storage layer 43 stores charge; and the cell transistors thereby function as the memory cells MC to store data.

In this specific example, the charge storage layer 43 forming the storage unit is provided continuously in the interior of the through-hole TH. However, the invention is not limited thereto. For example, the charge storage layer 43 may be provided discontinuously in the interior of the through-hole TH. Also, the charge storage layer 43 may be provided parallel to the electrode film WL via an insulating film. Thus, it is sufficient that the charge storage layer 43 (the storage unit) is provided corresponding to the intersections between the electrode films WL and the semiconductor pillar SR

Thus, the memory unit MU includes the stacked structural unit ML including the multiple electrode films WL alternately stacked with the multiple first insulating films 14 in the Z axis direction perpendicular to the major surface 11a; the semiconductor pillar SP piercing the stacked structural unit ML in the Z axis direction; and the charge storage layer 43 (the storage unit) provided corresponding to the intersections between the semiconductor pillar SP and the electrode films WL.

Although FIG. 1 and FIG. 2 illustrate the case of four electrode films WL, that is, the case where the stacked structural unit ML has four layers of the electrode films WL, any number of the electrode films WL may be provided in the stacked structural unit ML.

As illustrated in FIG. 3, the electrode film WL between the semiconductor pillars SP adjacent in the Y axis direction is divided by an insulating layer IL; and the electrode film WL is divided into a first region WR1 and a second region WR2.

As illustrated in FIG. 2, selection gate electrodes SG are provided on the stacked structural unit ML. The selection gate electrode SG may include any conductive material. For example, polysilicon may be used. The selection gate electrodes SG are formed by dividing a conductive film along a constant direction. In this specific example, the selection gate electrodes SG are divided in the Y axis direction. In other words, the selection gate electrodes SG have band configurations aligned along the X axis direction.

As illustrated in FIG. 1, an inter-layer insulating film 15 is provided in an uppermost portion of the stacked structural unit ML (on the side most distal to the semiconductor substrate 11). An inter-layer insulating film 16 is provided on the stacked structural unit ML; the selection gate electrodes SG are provided thereupon; and an inter-layer insulating film 17 is provided between the selection gate electrodes SG. A through-hole is made in the selection gate electrode SG; a selection gate insulating film SGI of a selection gate transistor is provided on an inner side face thereof; and a semiconductor is filled onto the inner side thereof. The semiconductor communicates with the semiconductor pillar SP.

An inter-layer insulating film 18 is provided on the inter-layer insulating film 17; and source lines SL and vias 22 are provided thereupon. An inter-layer insulating film 19 is provided around the source lines SL. The via 22 includes a stacked film of a barrier layer 20 and a metal layer 21. The barrier layer 20 may include, for example, Ti—Tin. The metal layer 21 may include, for example, tungsten. Similarly, the source line SL may include a stacked film of, for example, a barrier layer of Ti—TiN, etc., and a metal layer of tungsten, etc.

An inter-layer insulating film is provided on the source lines SL; and bit lines BL are provided thereupon. The bit lines BL have band configurations along the Y axis. The bit line may include, for example, Cu. The inter-layer insulating films 15, 16, 17, 18, 19, and 23 and the selection gate insulating film SGI may include, for example, silicon oxide.

The electrode film WL is a conductive film parallel to the XY plane and is divided, for example, into units of erasing blocks.

Multiple through-holes TH are made in the stacked structural unit ML and the selection gate electrodes SG to align in the stacking direction (the Z axis direction); an insulating film is provided on the side faces of the interiors thereof; and a semiconductor material is filled into the spaces of the inner sides thereof to form the semiconductor pillars SP. In other words, the semiconductor pillar SP provided in the stacked structural unit ML also pierces the selection gate electrode SG of the upper portion of the stacked structural unit ML.

In this specific example, two of the semiconductor pillars SP are connected on the semiconductor substrate 11 side.

In other words, the nonvolatile semiconductor memory device 110 further includes a first connection portion CP1 to electrically connect the first semiconductor pillar SP1 to a second semiconductor pillar SP2 on the semiconductor substrate 11 side. Restated, the first and second semiconductor pillars SP1 and SP2 are connected by the first connection portion CP1 and function as one NAND string having a U-shaped configuration. The first connection portion CP1 opposes a back gate BG.

However, the invention is not limited thereto. As described below, each of the semiconductor pillars SP may be independent and may not be connected by a connection portion CP on the semiconductor substrate 11 side. In such a case, a selection gate electrode is provided at each of the upper portion and the lower portion of the stacked structural unit ML to select each of the semiconductor pillars SP. The case will now be described where two of the semiconductor pillars SP are connected by the first connection portion CP1.

Herein, the semiconductor pillar is multiply provided in the nonvolatile semiconductor memory device 110. “Semiconductor pillar SP” is used to refer to all of the semiconductor pillars or any semiconductor pillar; and “nth semiconductor pillar SPn” (n being any integer not less than 1) is used to refer to a designated semiconductor pillar when describing the relationship among designated semiconductor pillars, etc. This similarly applies to the other components. For example, “connection portion CP” is used to refer to all of the connection portions or any connection portion; and “nth connection portion CPn” (n is any integer not less than 1) is used to refer to a designated connection portion.

As illustrated in FIG. 2, the first and second semiconductor pillars SP1 and SP2 are connected as a pair by the first connection portion CP1 to form one NAND string having a U-shaped configuration. The third and fourth semiconductor pillars SP3 and SP4 are connected as a pair by a second connection portion CP2 to form another NAND string having a U-shaped configuration.

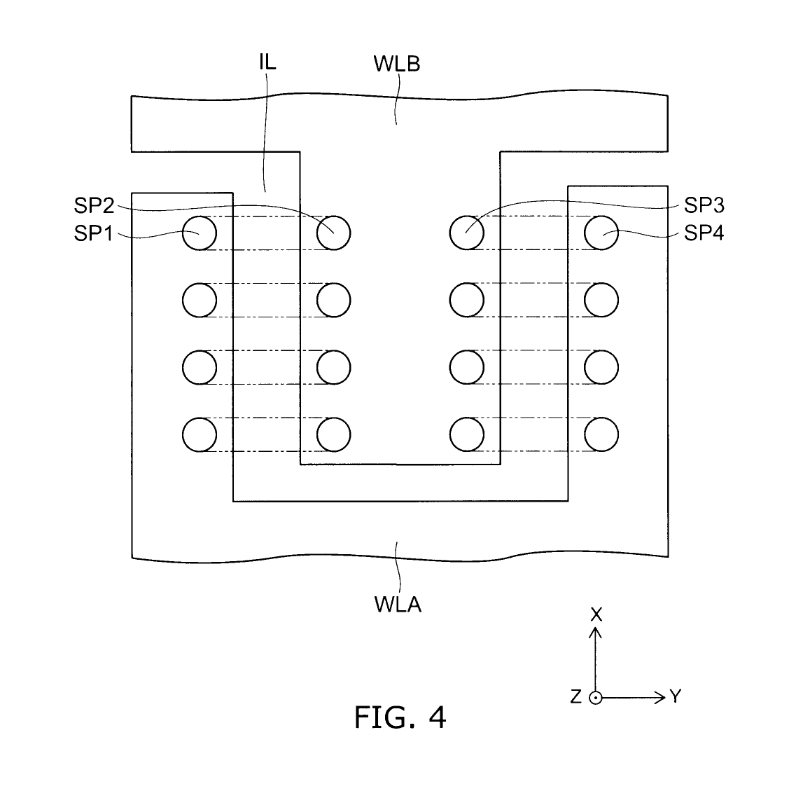

FIG. 4 is a schematic plan view illustrating the configuration of the electrode films of the nonvolatile semiconductor memory device according to the first embodiment of the invention.

As illustrated in FIG. 4, for the electrode films WL, the electrode films corresponding to the semiconductor pillars SP(4m+1) and SP(4m+4) are commonly connected to form an electrode film WLA, where m is an integer not less than 0 and n recited above is (4m+1) and (4m+4); and the electrode films corresponding to the semiconductor pillars SP(4m+2) and SP(4m+3) are commonly connected to form an electrode film WLB, where n is (4m+2) and (4m+3). In other words, the electrode films WL have a configuration in which the electrode film WLA and the electrode film WLB are combined with each other in a comb teeth configuration opposing in the X-axis direction.

As illustrated by the interconnect connection unit MU2 illustrated in FIG. 1, the electrode film WLB is connected at one end in the X axis direction to a word line 32 by a via plug 31 and is electrically connected to, for example, a drive circuit provided on the substrate 11. Similarly, the electrode film WLA is connected at the other end in the X axis direction to the word line by the via plug and is electrically connected to the drive circuit. In other words, the length in the X axis direction of each of the electrode films WL (the electrode films WLA and the electrode films WLB) stacked in the Z axis direction changes in a stairstep configuration; and the electrode films WL are electrically connected to the drive circuit by the electrode films WLA at one end in the X axis direction and by the electrode films WLB at the other end in the X axis direction.

Thereby, for the electrode films WL at the same distance from the substrate 11, different potentials can be set for the pair of the first semiconductor pillar SP1 and the second semiconductor pillar SP2. Also, for the electrode films WL at the same distance from the substrate 11, different potentials can be set for the third semiconductor pillar SP3 and the fourth semiconductor pillar SP4. Thereby, the memory cells of the same layer corresponding to the first semiconductor pillar SP1 and the second semiconductor pillar SP2 can be operated independently from each other; and the memory cells of the same layer corresponding to the third semiconductor pillar SP3 and the fourth semiconductor pillar SP4 can be operated independently from each other.

The combination of the electrode film WLA and the electrode film WLB can be taken to be one erasing block; and the electrode film WLA and the electrode film WLB can be divided from other electrode films WLA and electrode films WLB for each erasing block.

The number of the semiconductor pillars included in each of the erasing blocks in the X axis direction and the Y axis direction is arbitrary.

The back gate BG is connected to a back gate interconnect 34 by a via plug 33.

The via plugs 31 and 33, the word line 32, and the back gate interconnect 34 may include, for example, a stacked film of a barrier layer of Ti—TiN, etc., and a metal layer of tungsten, etc.

As illustrated in FIG. 2, the end of the first semiconductor pillar SP1 opposite to the semiconductor substrate 11 is connected to the bit line BL; and the end of the second semiconductor pillar SP2 opposite to the semiconductor substrate 11 is connected to the source line SL. On the other hand, the end of the third semiconductor pillar SP3 opposite to the semiconductor substrate 11 is connected to the source line SL; and the end of the fourth semiconductor pillar SP4 opposite to the semiconductor substrate 11 is connected to the bit line BL. The first to fourth selection gate electrodes SG1 to SG4 are provided on the first to fourth semiconductor pillars SP1 to SP4. Thereby, the desired data can be written to or read from any of the memory cells MC of any of the semiconductor pillars SP.

In other words, the memory unit MU further includes the second semiconductor pillar SP2, the second storage unit (the charge storage layer 43), the first connection portion CP1, the bit line BL, and the source line SL.

The second semiconductor pillar SP2 is adjacent to the first semiconductor pillar SP1 in the Y axis direction and pierces the stacked structural unit ML in the Z axis direction. The second storage unit is provided corresponding to the intersections between the second semiconductor pillar SP2 and the electrode films WL. The first connection portion CP1 electrically connects the first semiconductor pillar SP1 to the second semiconductor pillar SP2 on the semiconductor substrate 11 side. The bit line BL is aligned in the Y axis direction and is connected to a first end portion of the first semiconductor pillar SP1 on the side opposite to the semiconductor substrate 11. The source line SL is aligned in the X axis direction and is connected to a second end portion of the second semiconductor pillar SP2 on the side opposite to the semiconductor substrate 11.

The memory unit MU further includes the third semiconductor pillar SP3, a third storage unit (the charge storage layer 43), the fourth semiconductor pillar SP4, a fourth storage unit (the charge storage layer 43), and the second connection portion CP2.

The third semiconductor pillar SP3 is adjacent to the second semiconductor pillar SP2 in the Y axis direction on the side of the second semiconductor pillar SP2 opposite to the first semiconductor pillar SP1 and pierces the stacked structural unit ML in the Z axis direction. The third storage unit is provided corresponding to the intersections between the third semiconductor pillar SP3 and the electrode films WL. The fourth semiconductor pillar SP4 is adjacent to the third semiconductor pillar SP3 in the Y axis direction on the side of the third semiconductor pillar SP3 opposite to the second semiconductor pillar SP2 and pierces the stacked structural unit ML in the Z axis direction. The fourth storage unit is provided corresponding to the intersections between the fourth semiconductor pillar SP4 and the electrode films WL. The second connection portion CP2 electrically connects the third semiconductor pillar SP3 to the fourth semiconductor pillar SP4 on the semiconductor substrate 11 side.

The bit line BL is connected to a fourth end portion of the fourth semiconductor pillar SP4 on the side opposite to the semiconductor substrate 11. The source line SL is connected to a third end portion of the third semiconductor pillar SP3 on the side opposite to the semiconductor substrate 11.

Thus, in the nonvolatile semiconductor memory device 110, the various interconnects for the memory cells MC are provided above the stacked structural unit ML; and such interconnects are not provided on the semiconductor substrate 11 side. Therefore, as illustrated in FIG. 1, the chip surface area can be further reduced by providing the circuit unit CU on the semiconductor substrate 11 below the stacked structural unit ML.

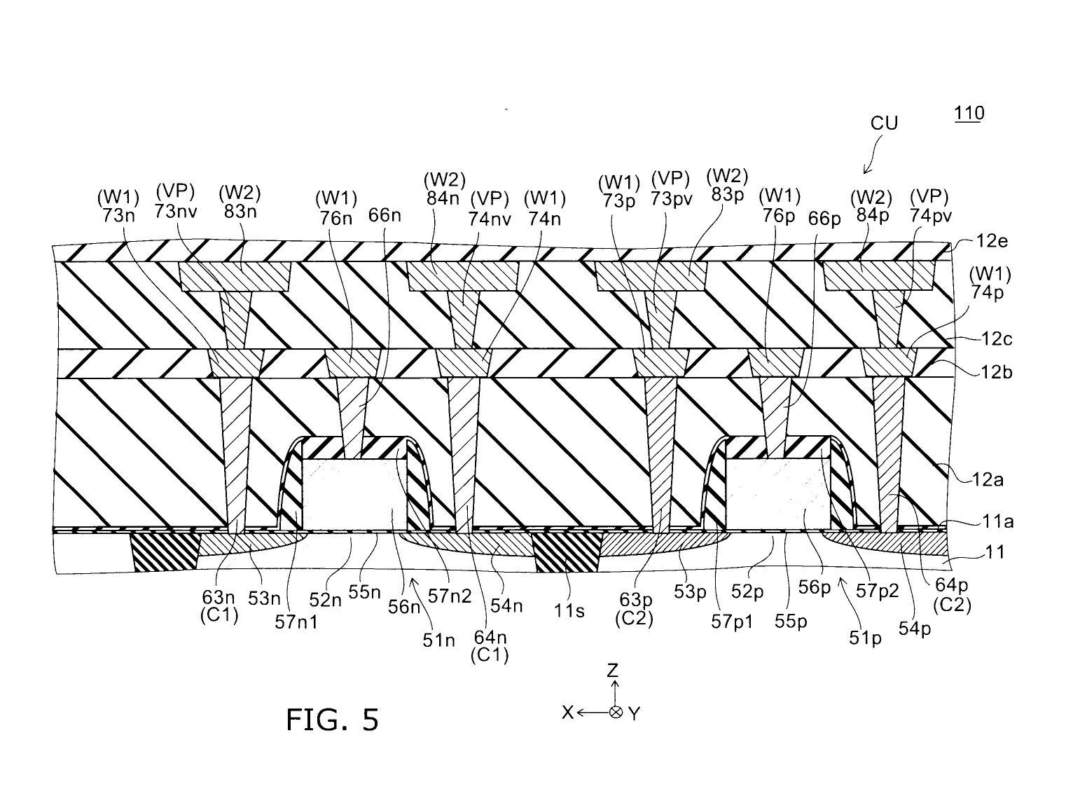

FIG. 5 is a schematic cross-sectional view illustrating the configuration of a circuit unit of the nonvolatile semiconductor memory device according to the first embodiment of the invention.

As illustrated in FIG. 5, the circuit unit CU includes a first transistor 51n of a first conductivity type and a second transistor 51p of a second conductivity type. The first conductivity type and the second conductivity type are mutually interchangeable. The case will now be described where the first conductivity type is an n-type and the second conductivity type is a p-type.

In other words, the first transistor 51n is an n-type FET (Field Effect Transistor); and the second transistor 51p is a p-type FET.

The first transistor 51n includes an n-type first source region 53n and an n-type first drain region 54n, where the first source region 53n is made of, for example, a diffusion layer and the first drain region 54n is made of, for example, a diffusion layer.

The first transistor 51n further includes a first channel region 52n between the first source region 53n and the first drain region 54n, a first gate insulating film 55n provided on the first channel region 52n, and a first gate electrode 56n provided on the first gate insulating film 55n. Further, an insulating film 57n1 made of, for example, silicon oxide is provided on the side faces and the upper face of the first gate electrode 56n; and an insulating film 57n2 made of, for example, silicon nitride is provided thereupon.

Contact plugs described below are connected to portions on the first source region 53n, the first drain region 54n, and the first gate electrode 56n through openings made in the insulating film 57n2 and an inter-layer insulating film 12a.

On the other hand, the second transistor 51p includes a p-type second source region 53p and a p-type second drain region 54p, where the second source region 53p is made of, for example, a diffusion layer and the second drain region 54p is made of, for example, a diffusion layer.

The second transistor 51p further includes a second channel region 52p between the second source region 53p and the second drain region 54p, a second gate insulating film 55p provided on the second channel region 52p, and a second gate electrode 56p provided on the second gate insulating film 55p. Further, an insulating film 57p1 made of, for example, silicon oxide is provided on the side faces and the upper face of the second gate electrode 56p; and an insulating film 57p2 made of, for example, silicon nitride is provided thereupon.

Contact plugs described below are connected to portions on the second source region 53p, the second drain region 54p, and the second gate electrode 56p through openings made in the insulating film 57p2 and the inter-layer insulating film 12a.

The first transistor 51n and the second transistor 51p are divided by, for example, an STI (Shallow Trench Insulator) 11s. The inter-layer insulating film 12a is made of, for example, silicon oxide and provided on the first transistor 51n, the second transistor 51p, and the semiconductor substrate 11.

An interconnect 73n, an interconnect 74n, and an interconnect 76n are provided above the first transistor 51n. On the other hand, an interconnect 73p, an interconnect 74p, and an interconnect 76p are provided above the second transistor 51p. The interconnect 73n, the interconnect 74n, the interconnect 76n, the interconnect 73p, the interconnect 74p, and the interconnect 76p are above the first transistor 51n and the second transistor 51p and form first interconnects W1 most proximal to the first transistor 51n and the second transistor 51p. An inter-layer insulating film 12b made of, for example, silicon oxide is provided among the interconnect 73n, the interconnect 74n, the interconnect 76n, the interconnect 73p, the interconnect 74p, and the interconnect 76p.

The first interconnect W1 is aligned, for example, in a direction perpendicular to the Z axis direction. However, the alignment direction of the first interconnect W1 is arbitrary. The length in which the first interconnect W1 is aligned and the width of the first interconnect W1 are arbitrary. The ratio of the length to the width of the first interconnect W1 is arbitrary; and the configuration of the first interconnect W1 is not necessarily a band configuration.

The first interconnect W1 includes a silicide. The silicide includes at least one selected from WSi₂ and TiSi₂. In this specific example, the interconnect 73n, the interconnect 74n, the interconnect 76n, the interconnect 73p, the interconnect 74p, and the interconnect 76p include WSi₂.

A contact plug 63n (a first contact plug C1) is provided to connect the interconnect 73n to the first source region 53n. A contact plug 64n (the first contact plug C1) is provided to connect the interconnect 74n to the first drain region 54n. The contact plug 63n and the contact plug 64n are made of n-type polysilicon.

On the other hand, a contact plug 63p (a second contact plug C2) is provided to connect the interconnect 73p to the second source region 53p. A contact plug 64p (the second contact plug C2) is provided to connect the interconnect 74p to the second drain region 54p. The contact plug 63p and the contact plug 64p are made of p-type polysilicon.

Thus, the circuit unit CU provided between the semiconductor substrate 11 and the memory unit MU includes: the first transistor 51n including the first source region 53n of the n-type and the first drain region 54n of the n-type; the second transistor 51p including the second source region 53p of the p-type and the second drain region 54p of the p-type; the first interconnect W1 including silicide; the first contact plug C1 (the contact plugs 63n and 64n) made of n-type polysilicon connecting the first interconnect W1 to at least one selected from the first source region 53n and the first drain region 54n; and the second contact plug C2 (the contact plugs 63p and 64p) made of p-type polysilicon connecting the first interconnect W1 to at least one selected from the second source region 53p and the second drain region 54p.

Thus, the circuit unit CU of the nonvolatile semiconductor memory device 110 uses contact plugs made of polysilicon of the same conductivity types as those of the source regions and the drain regions of the transistors to connect the source regions and the drain regions to the first interconnects W1. Therefore, even after the high-temperature processing exceeding 1000° C. during the formation of the memory unit MU performed after the formation of the circuit unit CU, contact defects due to agglomeration can be avoided.

Also, by using a silicide of a refractory metal instead of metal as the first interconnect W1, deterioration of the contact characteristics of the contact plugs and contact characteristics with the first and second transistors 51n and 51p via the contact plugs can be suppressed during the high-temperature processing of the formation of the memory unit MU.

It is important for the first interconnect W1 not only to have a simple heat resistance to the high temperatures experienced during the formation of the memory unit MU but also to have a low reactivity with the other members at the high temperatures. In particular, it is important to have a low reactivity at high temperatures with the silicon of the first and second transistors 51n and 51p and the polysilicon of the first and second contact plugs C1 and C2. In this aspect, it is desirable for the first interconnect W1 to include a silicide having a low reactivity with silicon and polysilicon. Of such silicides, it is more desirable to use WSi₂ and TiSi₂, which have particularly low reactivities.

In the case of a comparative example in which, for example, metal contact plugs are provided for the source regions and the drain regions of the transistors, contact defects easily occur between the metal contact plugs and the source and drain regions during the high-temperature processing exceeding 1000° C. during the subsequent formation of the memory unit MU.

Moreover, in the case of contact plugs of polysilicon having a conductivity type different from the conductivity type of the source region and the drain region of the transistor, a pn junction is formed, for example, between the contact plugs and the source and drain regions; and the desired contact characteristics cannot be obtained.

Therefore, in the nonvolatile semiconductor memory device 110 according to this embodiment, the first and second contact plugs C1 and C2 include polysilicon of the same conductivity type as the conductivity type of the source regions and the drain regions of the first and second transistors 51n and 51p.

In this specific example, the conductivity types of the first transistor 51n and the first gate electrode 56n are arbitrary. The conductivity type of a first gate contact plug 66n connecting the first gate electrode 56n to the interconnect 76n (the first interconnect W1) is the same as the conductivity type of the first gate electrode 56n.

Similarly, the conductivity types of the second transistor 51p and the second gate electrode 56p are arbitrary. The conductivity type of a second gate contact plug 66p connecting the second gate electrode 56p to the interconnect 76p (the first interconnect W1) is the same as the conductivity type of the second gate electrode 56p.

In this specific example, the circuit unit CU includes a second interconnect W2 provided above the first interconnect W1 and a via plug VP provided between the first interconnect W1 and the second interconnect W2 to electrically connect the first interconnect W1 and the second interconnect W2. In this specific example, the second interconnect W2 is silicide and the via plug VP also is silicide.

An inter-layer insulating film 12c is provided between the second interconnects W2 and between the via plugs VP; and an inter-layer insulating film 12e is provided on the second interconnects W2.

The second interconnect W2 is aligned, for example, in a direction perpendicular to the Z axis direction. However, the alignment direction of the second interconnect W2 is arbitrary. The length in which the second interconnect W2 is aligned and the width of the second interconnect W2 are arbitrary. The ratio of the length to the width of the second interconnect W2 is arbitrary; and the configuration of the second interconnect W2 is not necessarily a band configuration.

In other words, an interconnect 83n and an interconnect 84n, i.e., the second interconnects W2, are provided; a plug 73nv (the via plug VP) is provided to connect the interconnect 83n to the interconnect 73n; and a plug 74nv (the via plug VP) is provided to connect the interconnect 84n to the interconnect 74n. An interconnect 83p and an interconnect 84p, i.e., the second interconnects W2, are provided; a plug 73pv (the via plug VP) is provided to connect the interconnect 83p and the interconnect 73p; and a plug 74pv (the via plug VP) is provided to connect the interconnect 84p and the interconnect 74p.

In this specific example, the interconnects 83n, 84n, 83p, and 84p (the second interconnects W2) and the plugs 73nv, 74nv, 73pv, and 74pv (the via plugs VP) are silicide. However, the invention is not limited thereto. The second interconnect W2 may be, for example, metal instead of silicide.

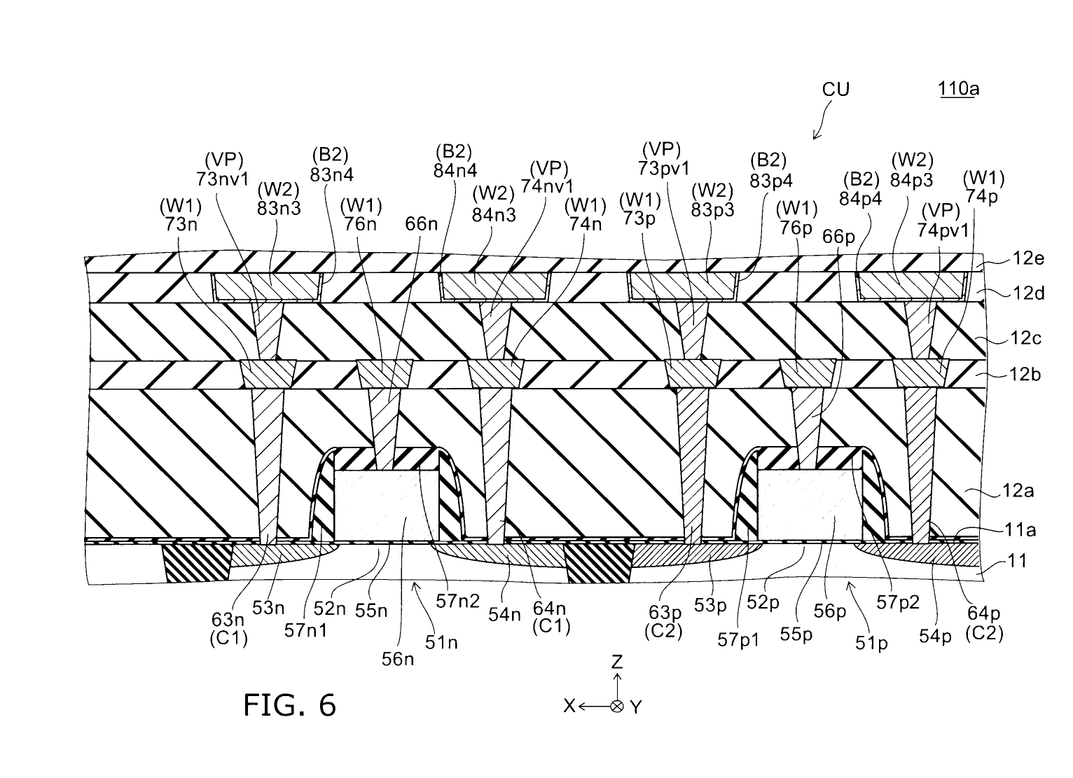

FIG. 6 is a schematic cross-sectional view illustrating the configuration of the circuit unit of another nonvolatile semiconductor memory device according to the first embodiment of the invention.

In the circuit unit CU of another nonvolatile semiconductor memory device 110a according to this embodiment, metal is used as the second interconnect W2 (interconnects 83n3, 84n3, 83p3, and 84p3) as illustrated in FIG. 6. In this specific example, the interconnects 83n3, 84n3, 83p3, and 84p3 include tungsten. A barrier metal B2 (Ti—TiN films 83n4, 84n4, 83p4, and 84p4) are stacked with these interconnects. The electrical resistance of the second interconnect W2 is lower than the electrical resistance of the first interconnect.

Thus, in the nonvolatile semiconductor memory device 110a, the circuit unit CU further includes the barrier metal B2 (a conductive layer) provided to cover at least a portion of a face of the second interconnect W2 on the semiconductor substrate 11 side, where the barrier metal B2 is made of a material having a reactivity with silicon lower than that of the second interconnect W2.

The via plug VP (plugs 73nv1, 74nv1, 73pv1, and 74pv1) connecting the first interconnect W1 to the second interconnect W2 includes TiN, which has a reactivity with silicon lower than the reactivity of tungsten with silicon.

The inter-layer insulating film 12c is provided between the via plugs VP; an inter-layer insulating film 12d is provided between the second interconnects W2; and the inter-layer insulating film 12e is provided on the second interconnects W2. Otherwise, the nonvolatile semiconductor memory device 110a is similar to the nonvolatile semiconductor memory device 110, and a description is omitted.

In the nonvolatile semiconductor memory device 110a, tungsten, which has a lower resistance than that of WSi₂, is used as the second interconnect W2. Therefore, the resistance of the interconnects can be reduced. Faster operations are possible in the nonvolatile semiconductor memory device 110a than in the nonvolatile semiconductor memory device 110 in which WSi₂ is used for both the first interconnect W1 and the second interconnect W2.

Although there is a risk of reactions with the silicide of the first interconnect W1 in the case where metal is used as the second interconnect W2, in the nonvolatile semiconductor memory device 110a according to this embodiment, TiN, which has a low reactivity with silicon, is used as the via plug VP connecting the first interconnect W1 to the second interconnect W2. Therefore, contact defects substantially do not occur between the metal second interconnect W2 and the silicide first interconnect W1 even when high-temperature processing is performed.

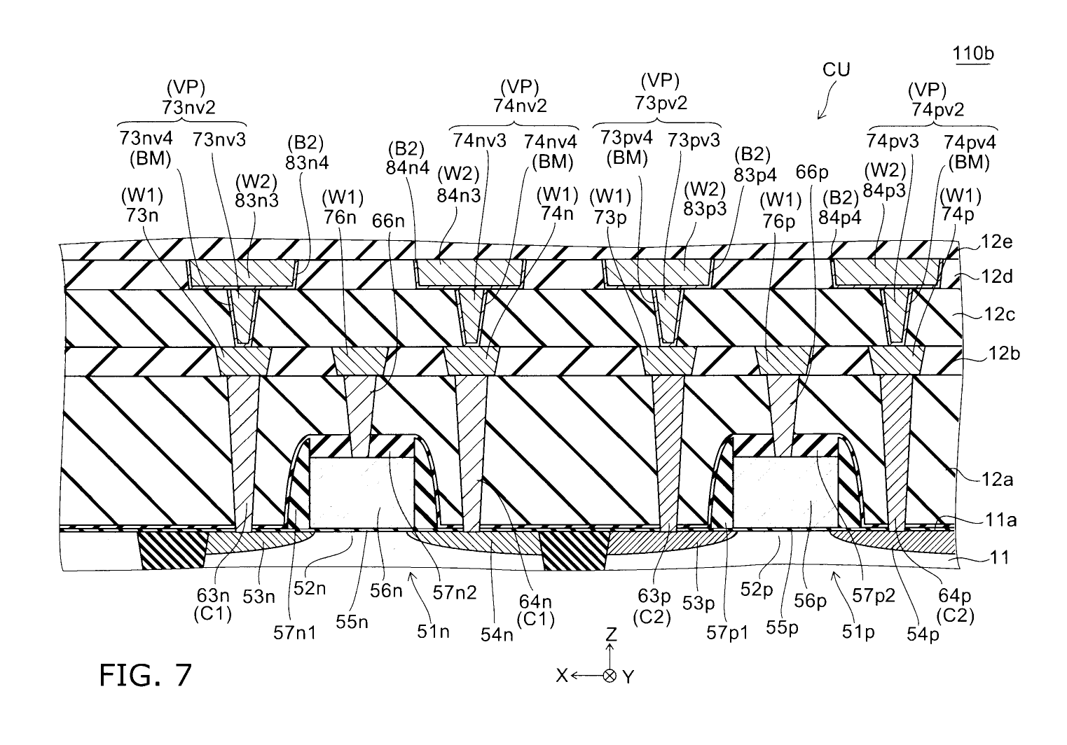

FIG. 7 is a schematic cross-sectional view illustrating the configuration of the circuit unit of another nonvolatile semiconductor memory device according to the first embodiment of the invention.

In the circuit unit CU of another nonvolatile semiconductor memory device 110b according to this embodiment, a stacked film is used as the via plug VP (plugs 73nv2, 74nv2, 73pv2, and 74pv2) connecting the first interconnect W1 to the second interconnect W2 as illustrated in FIG. 7. Otherwise, the nonvolatile semiconductor memory device 110b is similar to the nonvolatile semiconductor memory device 110a, and a description is omitted.

In other words, the plug 73nv2 includes a stacked film of a TiN layer 73nv4 contacting the first interconnect W1 and a metal layer 73nv3 contacting the second interconnect W2. The plug 73nv2 is formed by making a via hole to reach the first interconnect W1, forming the TiN layer 73nv4 on the inner side face of the via hole, and filling a metal material into the remaining space of the via hole to form the metal layer 73nv3. At this time, the filling of the metal material into the via hole may simultaneously fill the metal material into the trench to form the interconnect 83n3. In other words, the forming of the metal layer 73nv3 may be performed simultaneously with the forming of the second interconnect W2.

Similarly, the plug 74nv2 includes a stacked film of a TiN layer 74nv4 contacting the first interconnect W1 and a metal layer 74nv3 contacting the second interconnect W2. The plug 73pv2 includes a stacked film of a TiN layer 73pv4 contacting the first interconnect W1 and a metal layer 73pv3 contacting the second interconnect W2. The plug 74pv2 includes a stacked film of a TiN layer 74pv4 contacting the first interconnect W1 and a metal layer 74pv3 contacting the second interconnect W2.

The TiN layers 73nv4, 74nv4, 73pv4, and 74pv4 form barrier metals BM.

In the nonvolatile semiconductor memory device 110b as well, the resistance of the interconnects can be reduced because tungsten, which has a low resistance, is used as the second interconnect W2.

Because the TiN layer barrier metal BM is used as the via plug VP, contact defects substantially do not occur between the metal layers 73nv3, 74nv3, 73pv3, and 74pv3 of the via plugs VP and the silicide of the first interconnects W1 even when a high-temperature processing is performed.

Thus, the circuit unit CU may further include the second interconnect W2 provided on the first interconnect W1 and a conductive unit provided between the first interconnect W1 and the second interconnect W2, where the second interconnect is made of metal and the conductive unit is made of a material having a reactivity with silicon lower than the reactivity of the second interconnect W2 with silicon. In the case of the nonvolatile semiconductor memory device 110a, the conductive unit is the via plug VP (the plugs 73nv1, 74nv1, 73pv1, and 74pv1). In the case of the nonvolatile semiconductor memory device 110b, the conductive unit is the barrier metal BM (the metal layers 73nv3, 74nv3, 73pv3, and 74pv3).

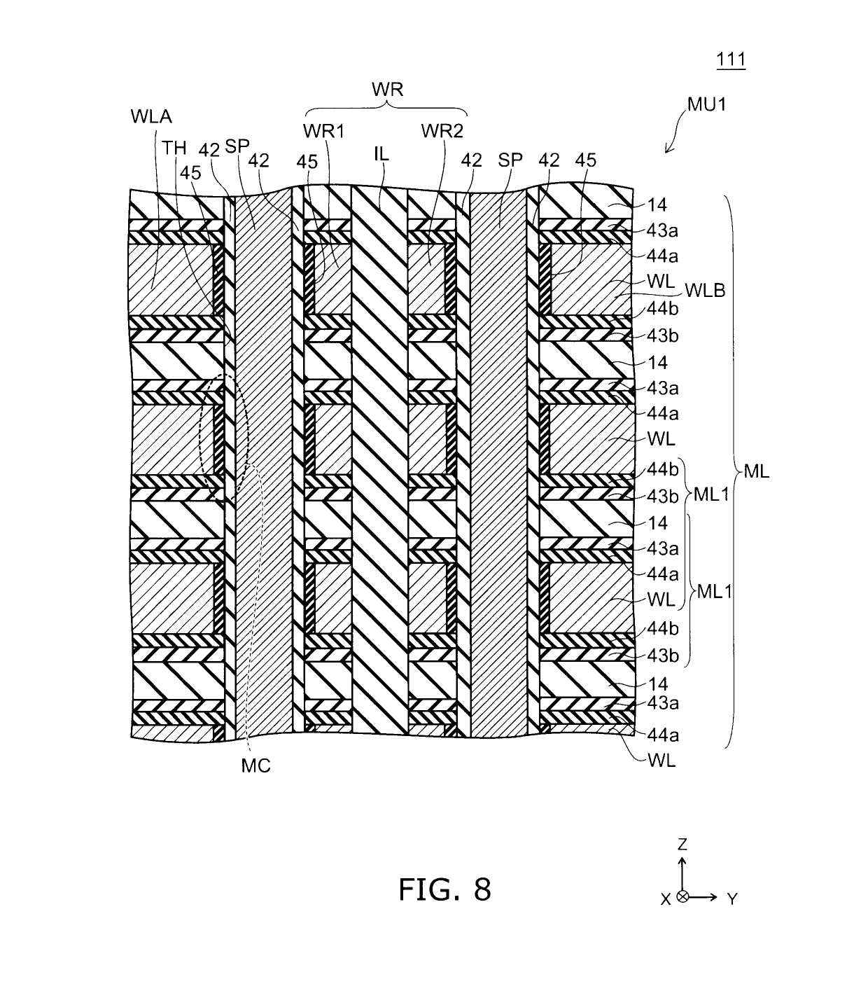

FIG. 8 is a schematic cross-sectional view illustrating the configuration of a portion of another nonvolatile semiconductor memory device according to the first embodiment of the invention.

Namely, FIG. 8 illustrates the configuration of the matrix memory cell unit MU1.

In a nonvolatile semiconductor memory device 111, the third insulating film 42 is provided on the inner side of the through-hole TH; and the semiconductor pillar SP is provided on the inner side thereof as illustrated in FIG. 8. Charge storage layers 43a and 43b and second insulating films 44a and 44b are provided parallel to the electrode film WL. The second insulating film 44a is provided between the charge storage layer 43a and the electrode film WL; and the second insulating film 44a is provided between the charge storage layer 43b and the electrode film WL.

In such a case as well, the memory cells MC are formed corresponding to the portions where the electrode films WL intersect the semiconductor pillar SP. In the memory cells MC, the charge storage layers 43a and 43b provided above and below each of the electrode films WL form storage units. The second insulating films 44a and 44b function as blocking insulating layers; and the third insulating film 42 functions as a tunneling insulating film.

In the case of the memory unit MU having such a configuration as well, by providing the circuit unit CU described above therebelow, the memory cell unit can be formed in a portion above the circuit unit; and the interconnect layers and contacts of the circuit unit do not deterioration even when the circuit unit is exposed to high temperatures.

Although the charge storage layer 43a or 43b is provided above and below the electrode film WL in the nonvolatile semiconductor memory device 111, the charge storage layer 43a or the charge storage layer 43b may be provided only on one selected from above and below the electrode film WL.

As in the nonvolatile semiconductor memory devices 110, 110a, 110b, and 111 recited above, in the case where a memory string having a U-shaped structure is used, the interconnects to the source line SL, the bit line BL, the word line WL, and the like connected to the memory cells MC can be provided on the upper side of the memory cells MC. Therefore, the chip surface area can be reduced easily by practically using the lower side of the memory cells MC, i.e., on the substrate of the memory array region MR. In other words, the chip surface area can be further reduced by disposing the circuit unit CU, which is at least a portion of the peripheral circuit, in the memory array region MR; and cost reductions are easier. The circuit unit CU recited above can be applied particularly effectively in such a configuration.

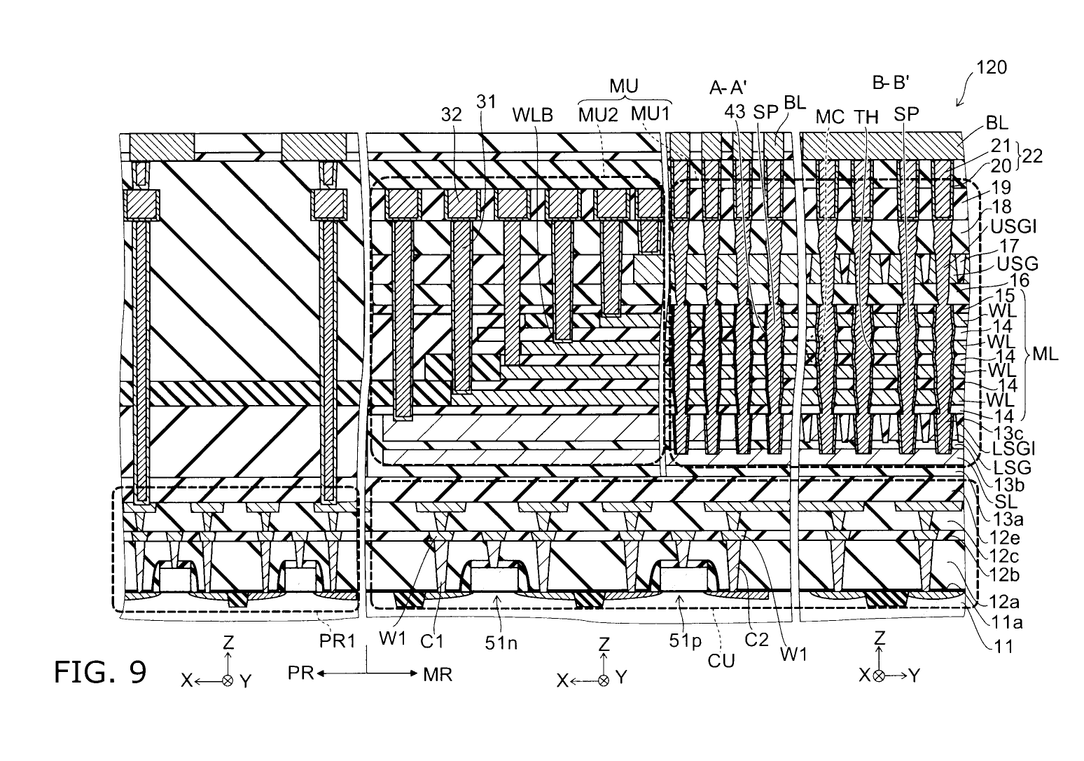

FIG. 9 is a schematic cross-sectional view illustrating the configuration of another nonvolatile semiconductor memory device according to the first embodiment of the invention.

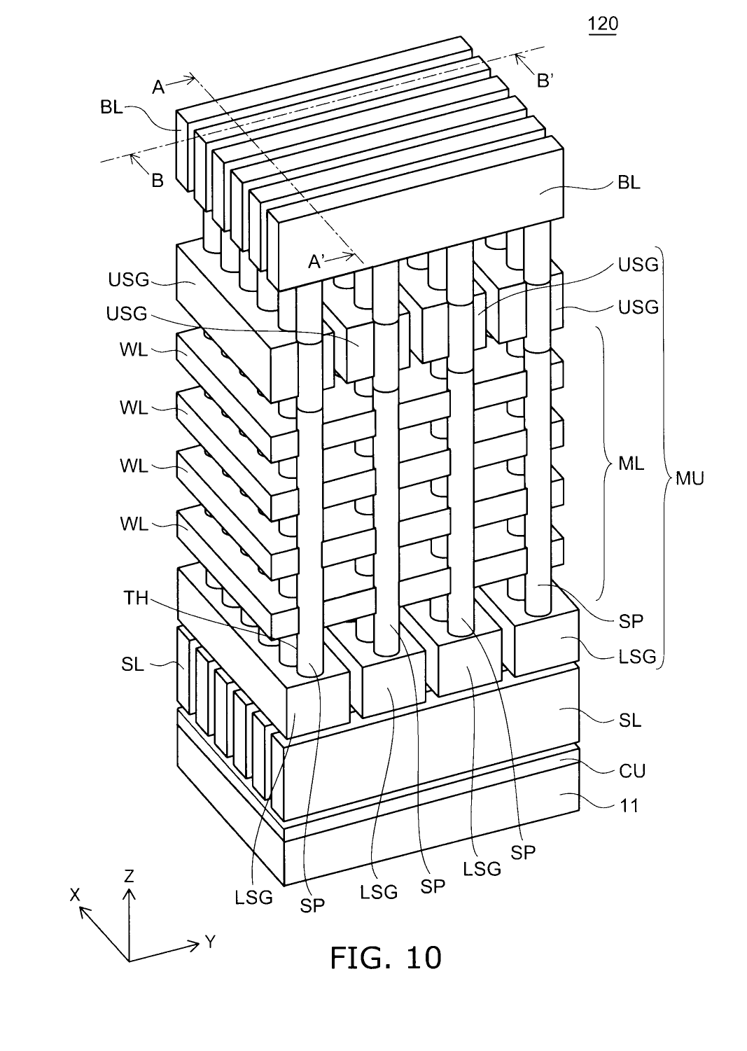

FIG. 10 is a schematic perspective view illustrating the configuration of another nonvolatile semiconductor memory device according to the first embodiment of the invention.

For easier viewing of the drawing in FIG. 10, only the conductive portions are illustrated, and the insulating portions are omitted.

In a nonvolatile semiconductor memory device 120 according to this embodiment, the semiconductor pillars SP are not connected in a U-shaped configuration; and each of the semiconductor pillars SP are independent as illustrated in FIG. 9 and FIG. 10. An upper selection gate electrode USG is provided on the stacked structural unit ML; and a lower selection gate electrode LSG is provided below the stacked structural unit ML.

An upper selection gate insulating film USGI made of, for example, silicon oxide is provided between the upper selection gate electrode USG and the semiconductor pillar SP. A lower selection gate insulating film LSGI made of, for example, silicon oxide is provided between the lower selection gate electrode LSG and the semiconductor pillar SP.

The source line SL is provided on the lower side of the lower selection gate electrode LSG. An inter-layer insulating film 13a is provided below the source line SL; and an inter-layer insulating film 13b is provided between the source line SL and the lower selection gate electrode LSG.

The semiconductor pillar SP is connected to the source line SL below the lower selection gate electrode LSG. The semiconductor pillar SP is connected to the bit line BL above the upper selection gate electrode USG. The memory cells MC are formed in the stacked structural unit ML between the upper selection gate electrode USG and the lower selection gate electrode LSG. The semiconductor pillar SP functions as one NAND string having a straight-line configuration.

The upper selection gate electrodes USG and the lower selection gate electrodes LSG are divided in the Y axis direction by the inter-layer insulating film 17 and an inter-layer insulating film 13c, respectively. In other words, the upper selection gate electrodes USG and the lower selection gate electrodes LSG have band configurations aligned along the X axis direction.

On the other hand, the bit lines BL connected to the upper portions of the semiconductor pillars SP and the source lines SL connected to the lower portions of the semiconductor pillars SP have band configurations aligned in the Y axis direction.

In such a case, the electrode film WL is a conductive film having a plate configuration parallel to the XY plane.

In the case of the memory unit MU having such a configuration as well, the circuit unit CU described above can be provided therebelow. Thereby, the memory cell unit can be formed in a portion above the circuit unit; and the interconnect layers and contacts of the circuit unit do not deteriorate even when the circuit unit is exposed to high temperatures.

### Second Embodiment

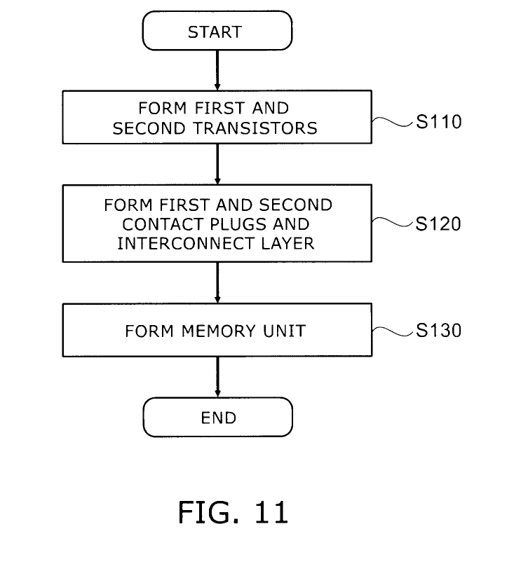

FIG. 11 is a flowchart illustrating a method for manufacturing a nonvolatile semiconductor memory device according to a second embodiment of the invention.

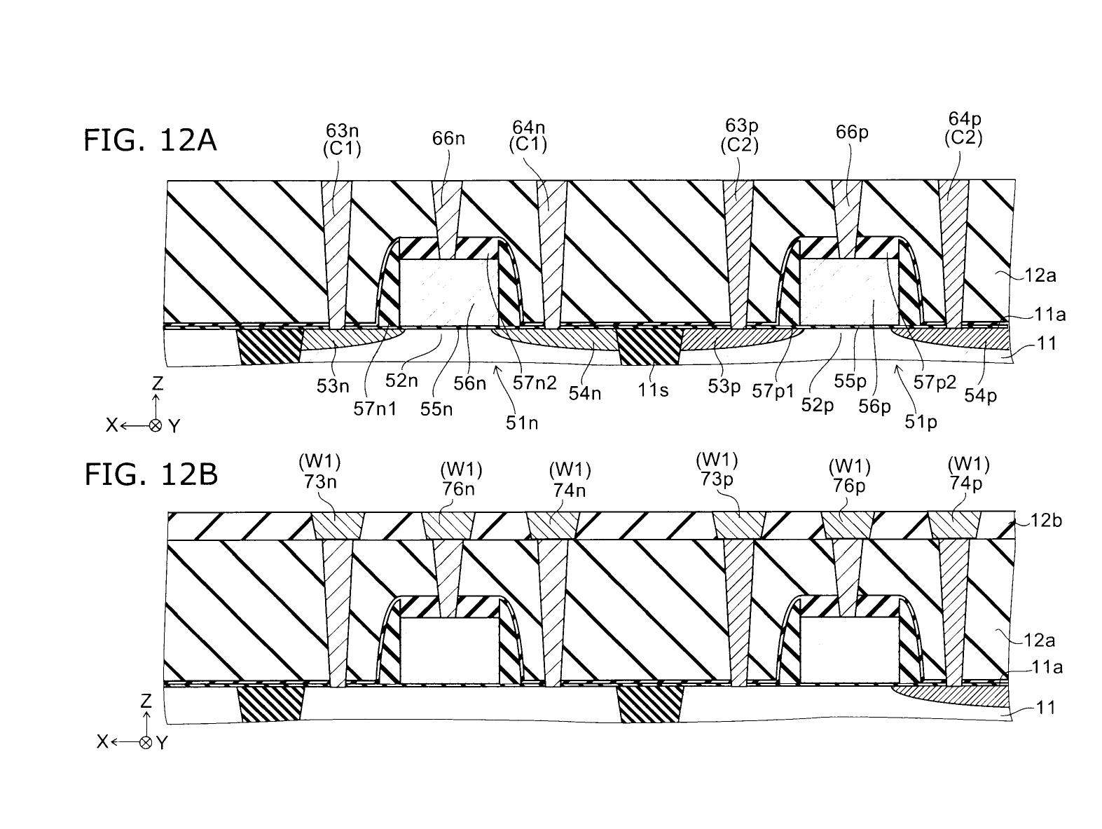

FIGS. 12A and 12B are schematic cross-sectional views in order of the processes, illustrating the method for manufacturing the nonvolatile semiconductor memory device according to the second embodiment of the invention.

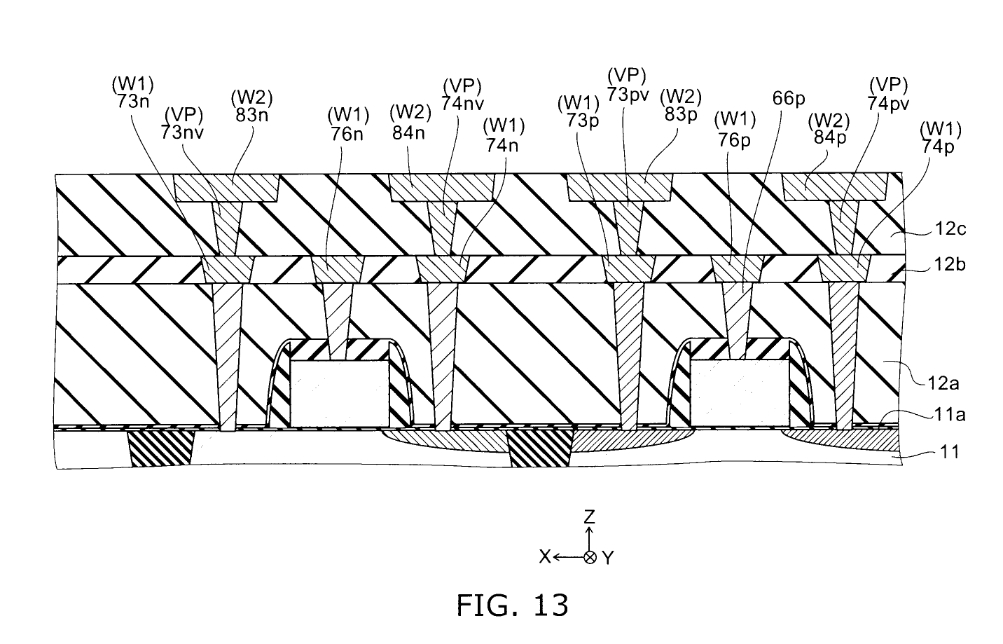

FIG. 13 is a schematic cross-sectional view in order of the processes, continuing from FIG. 12B.

In the method for manufacturing the nonvolatile semiconductor memory device according to this embodiment, first, the first transistor 51n and the second transistor 51p are formed on the major surface 11a of the semiconductor substrate 11, where the first transistor 51n includes the first source region 53n of the first conductivity type (e.g., the n-type) and the first drain region 54n of the first conductivity type, and the second transistor 51p includes the second source region 53p of the second conductivity type (e.g., the p-type) and the second drain region 54p of the second conductivity type as illustrated in FIG. 11 (step S110).

Then, the first contact plug C1, the second contact plug C2, and the first interconnect layer (the first interconnect W1) are formed (step S120).

In other words, the first contact plug C1 made of polysilicon of the first conductivity type is formed to align in the Z axis direction and connect to at least one selected from the first drain region 54n and the first source region 53n of the first transistor 51n; and the second contact plug C2 made of polysilicon of the second conductivity type is formed to align in the Z axis direction and connect to at least one selected from the second drain region 54p and the second source region 53p of the second transistor 51p.

Specifically, as illustrated in FIG. 12A, the first transistor 51n and the second transistor 51p are formed; and subsequently, the inter-layer insulating film 12a is formed thereupon. Then, holes are made through the inter-layer insulating film 12a and the insulating film 57n2 of the first transistor 51n to communicate with the first source region 53n, the first drain region 54n, and the first gate electrode 56n. Similarly, holes are made in the inter-layer insulating film 12a and the insulating film 57p2 of the second transistor 51p to communicate with the second source region 53p, the second drain region 54p, and the second gate electrode 56p. Polysilicon is filled into the holes. Subsequently, an n-type impurity is implanted into the polysilicon of the holes of the first transistor 51n, for example, in a state in which the second transistor 51p portion is shielded; and a p-type impurity is implanted into the polysilicon of the holes of the second transistor 51p in a state in which the first transistor 51n portion is shielded. In this specific example, a p-type impurity is implanted into the polysilicon of the hole communicating with the first gate electrode 56n of the second transistor 51p.

Subsequently, heat treatment is performed, the impurity is activated, and the first and second contact plugs C1 and C2 are formed.

In the description recited above, the formation methods of the first and second contact plugs C1 and C2 are arbitrary. In addition to methods, which implant impurities, methods may be used, for example, to selectively form separate films of polysilicon containing an n-type or p-type impurity; and various diffusing methods may be used.

As illustrated in FIG. 12B, the inter-layer insulating film 12b is formed thereupon; a trench for forming the first interconnect W1 is made in a prescribed portion of the inter-layer insulating film 12b; and silicide is filled into the trench to form the first interconnect W1 (the first interconnect layer). In other words, the first interconnect W1 including silicide is formed to connect to one selected from the first contact plug C1 and the second contact plug C2. To the extent of technical feasibility, a portion or all of the forming of the first and second contact plugs C1 and C2 and the forming of the first interconnect layer recited above may be implemented simultaneously; and a portion or all of the sequence is interchangeable.

Subsequently, as illustrated in FIG. 13, the inter-layer insulating film 12c is formed on the first interconnect W1; a hole and a trench having prescribed configurations are made; and the via plug VP and the second interconnect W2 are formed.

In other words, a conductive unit (the via plug VP) is formed between the first interconnect layer (the first interconnect W1) and the stacked structural unit ML to electrically connect to the first interconnect layer; and the second interconnect layer (the second interconnect W2) made of metal is further formed above the first interconnect layer to electrically connect to the conductive unit, where the second interconnect layer has a reactivity with silicon higher than that of the conductive unit.

Then, the inter-layer insulating film 12e is formed thereupon; and the circuit unit CU illustrated in FIG. 5 can be formed. As described above in regard to FIG. 5, the via plug VP and the second interconnect W2 may include silicide.

As described above in regard to FIG. 6, in the case where metal is used as the second interconnect W2, the via plug VP may include a material having a reactivity with silicon lower than the reactivity of the second interconnect W2 with silicon. Also, as described above in regard to FIG. 7, the via plug VP may include a stacked film of the barrier metal BM and metal.

In other words, to form the second interconnect layer, for example, a trench is made to communicate with the conductive unit; a conductive layer (the barrier metal BM) is formed on the inner side of the trench, where the conductive layer is made of a material having a reactivity with silicon lower than the reactivity of the second interconnect layer with silicon; and metal forming the second interconnect layer is filled into the remaining space of the trench.

Thereby, the circuit unit CU can be formed on the semiconductor substrate 11.

Then, the memory unit MU is formed on the circuit unit CU (step S130). The memory unit MU is provided above the first interconnect layer (the first interconnect W1) (in this specific example, above the second interconnect W2 above the first interconnect W1). The memory unit MU includes the stacked structural unit ML having multiple electrode films WL alternately stacked with multiple insulating films 14 in the Z axis direction, the semiconductor pillar SP piercing the stacked structural unit ML in the Z axis direction, and the storage unit (the charge storage layer 43) provided corresponding to the intersections between the semiconductor pillar SP and the electrode films WL.

Thereby, the memory unit MU may can be formed in a portion above the circuit unit CU; and the deterioration of the first interconnect layer (the first interconnect W1) and the contacts (the connection of the first and second contact plugs C1 and C2 with the transistors) of the circuit unit CU can be suppressed even when the circuit unit CU is exposed to a high temperature of, for example, 1000° C. or more.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the invention is not limited to these specific examples. For example, one skilled in the art may appropriately select specific configurations of components of nonvolatile semiconductor memory devices such as semiconductor substrates, electrode films, insulating films, insulating layers, stacked structural units, charge storage layers, semiconductor pillars, word lines, bit lines, source lines, and the like from known art and similarly practice the invention. Such practice is included in the scope of the invention to the extent that similar effects thereto are obtained.

Further, any two or more components of the specific examples may be combined within the extent of technical feasibility; and are included in the scope of the invention to the extent that the purport of the invention is included.

Moreover, all nonvolatile semiconductor memory devices and methods for manufacturing nonvolatile semiconductor memory devices practicable by an appropriate design modification by one skilled in the art based on the nonvolatile semiconductor memory devices and the methods for manufacturing nonvolatile semiconductor memory devices described above as exemplary embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention. For example, additions, deletions, or design modifications of components or additions, omissions, or condition modifications of processes appropriately made by one skilled in the art in regard to the embodiments described above are within the scope of the invention to the extent that the purport of the invention is included.

1. A nonvolatile semiconductor memory device, comprising:
a semiconductor substrate;
a memory unit; and
a circuit unit provided between the semiconductor substrate and the memory unit,
the memory unit including:
a stacked structural unit having a plurality of electrode films alternately stacked with a plurality of inter-electrode-film insulating films in a first direction perpendicular to a major surface of the substrate;
a first semiconductor pillar piercing the stacked structural unit in the first direction; and
a first storage unit provided corresponding to an intersection between the electrode films and the first semiconductor pillar,
the circuit unit including:
a first transistor having a first source region of a first conductivity type and a first drain region of the first conductivity type;
a second transistor having a second source region of a second conductivity type and a second drain region of the second conductivity type;
a first interconnect including silicide provided on a side of the first transistor and the second transistor opposite to the semiconductor substrate;
a first contact plug made of polysilicon of the first conductivity type electrically connecting the first interconnect to at least one selected from the first source region and the first drain region; and
a second contact plug made of polysilicon of the second conductivity type electrically connecting the first interconnect to at least one selected from the second source region and the second drain region.

2. The device according to claim 1, wherein the silicide contained in the first interconnect includes at least one selected from WSi₂ and TiSi₂.

3. The device according to claim 1, wherein the circuit unit further includes
a second interconnect made of metal provided above the first interconnect, and
a conductive unit connecting the first interconnect and the second interconnect, the conductive unit being made of a material having a reactivity with silicon lower than a reactivity of the second interconnect with silicon.

4. The device according to claim 3, wherein an electrical resistance of the second interconnect is lower than an electrical resistance of the first interconnect.

5. The device according to claim 3, wherein the first interconnect includes tungsten silicide and the second interconnect includes tungsten.

6. The device according to claim 3, wherein
the second interconnect includes tungsten, and
the conductive unit includes at least one selected from Ti and TiN.

7. The device according to claim 3, wherein the circuit unit further includes a conductive layer provided to cover at least a portion of a face of the second interconnect on the semiconductor substrate side, the conductive layer being made of a material having a reactivity with silicon lower than the reactivity of the second interconnect with silicon.

8. The device according to claim 1, wherein:
the first transistor further includes a first channel region provided between the first source region and the first drain region, a first gate insulating film provided on the first channel region, and a first gate electrode provided on the first gate insulating film; and
the second transistor further includes a second channel region provided between the second source region and the second drain region, a second gate insulating film provided on the second channel region, and a second gate electrode provided on the second gate insulating film.

9. The device according to claim 1, wherein the first transistor and the second transistor are divided by an STI (Shallow Trench Insulator).

10. The device according to claim 1, wherein the electrode films include at least one selected from amorphous silicon including an impurity and polysilicon including an impurity.

11. The device according to claim 1, wherein the inter-electrode-films insulating film include silicon oxide.

12. The device according to claim 1, wherein the first storage unit includes a charge storage layer provided between the electrode films and a side face of the first semiconductor pillar.

13. The device according to claim 12, further comprising: a first outer side insulating film provided between the first storage unit and each of the electrode films; and a first inner side insulating film provided between the first storage unit and the first semiconductor pillar.

14. The device according to claim 1, wherein the memory unit further includes:
a second semiconductor pillar piercing the stacked structural unit in the first direction;
a second storage unit provided corresponding to an intersection between the electrode films and the second semiconductor pillar; and
a connection portion electrically connecting the first semiconductor pillar and the second semiconductor pillar.

15. A method for manufacturing a nonvolatile semiconductor memory device, comprising:
forming a first transistor and a second transistor on a major surface of a semiconductor substrate, the first transistor including a first source region of a first conductivity type and a first drain region of the first conductivity type, the second transistor including a second source region of a second conductivity type and a second drain region of the second conductivity type;
forming a first contact plug, a second contact plug, and a first interconnect layer, the first contact plug being made of polysilicon of the first conductivity type and aligned in a first direction perpendicular to the major surface to connect to at least one selected from the first source region and the first drain region, the second contact plug being made of polysilicon of the second conductivity type and aligned in the first direction to connect to at least one selected from the second source region and the second drain region, the first interconnect layer including silicide and being connected to one selected from the first contact plug and the second contact plug; and
forming a memory unit above the first interconnect layer, the memory unit including:
a stacked structural unit having a plurality of electrode films alternately stacked with a plurality of inter-electrode-film insulating films in the first direction;
a first semiconductor pillar piercing the stacked structural unit in the first direction; and
a first storage unit provided corresponding to an intersection between the electrode films and the first semiconductor pillar.

16. The method according to claim 15, wherein the silicide contained in the first interconnect layer includes at least one selected from WSi₂ and TiSi₂.

17. The method according to claim 15, comprising:
forming, between the first interconnect layer and the stacked structural unit, a conductive unit electrically connected to the first interconnect layer; and
further forming, above the first interconnect layer and between the first interconnect layer and the stacked structural unit, a second interconnect layer made of metal having a reactivity with silicon higher than a reactivity of the conductive unit with silicon, the second interconnect layer being electrically connected to the conductive unit.

18. The method according to claim 17, wherein
the second interconnect layer includes tungsten, and
the conductive unit includes at least one selected from Ti and TiN.

19. The method according to claim 17, wherein the forming of the second interconnect layer includes:
making a trench and forming a conductive layer on an inner side of the trench, the trench communicating with the conductive unit, the conductive layer being made of a material having a reactivity with silicon lower than the reactivity of the second interconnect layer with silicon; and
filling a metal forming the second interconnect layer into a remaining space of the trench.

20. The method according to claim 19, wherein
the conductive layer includes at least one selected from Ti and TiN, and
the metal forming the second interconnect layer includes tungsten.
